(19) United States
(12) Patent Application Publication
(10) Pub. No.: US 2011/0111131 A1
(43) Pub. Date: May 12, 2011

(54) METHOD FOR PRODUCING A MULTICOMPONENT, POLYMER- AND METAL-CONTAINING LAYER SYSTEM, DEVICE AND COATED ARTICLE

(75) Inventors: Michael Vergöhl, Cremlingen-Destedt (DE); Thomas Neubert, Branschweig (DE)

(73) Assignee: Fraunhofer-Gesellschaft zur Forderung der angewandten Forschung e.V., Munich (DE)

(21) Appl. No.: 12/934,603

(22) PCT Filed: Mar. 27, 2008
(86) PCT No.: PCT/EP2008/002648

§ 371 Date: Jan. 13, 2011

(51) Int. Cl. C23C 14/46; C23C 16/452

(52) U.S. Cl. 427/523; 118/724

(57) ABSTRACT

A method for producing layer systems on substrates includes irradiating a first vacuum coating source with an irradiating source. The first vacuum coating source includes a first layer material that is dissolved in a solvent. A second vacuum coating source is applied to the substrate via a chemical vapor deposition process. In this way, novel layer systems and mixed layers, in particular mixed layers of polymers and metals or metal oxides can be applied.

### CROSS REFERENCE TO RELATED APPLICATIONS

The present application is a national phase application of PCT application PCT/EP2008/002648 filed pursuant to 35 U.S.C. §371, which application is incorporated herein by reference in its entirety.

### TECHNICAL FIELD

The invention relates to a method for producing a layer system on a substrate, a system suitable for implementing the method and an article produced via the method.

### BACKGROUND

The production of layer systems on substrates is of great industrial significance. Layer systems thereby generally concern so-called thin-film systems which are applied on the substrate by chemical vapor deposition processes. The articles produced in this way are used in the most varied of fields of technology. For example, metal oxides which are sputtered on a substrate and are applied for example in the display, flat glass and automobile industry and also in precision optics and opthalmics.

On very soft and elastic plastic material substrates, process-related technical advantages, such as the particularly high hardness and density of the applied layer, are partially reversed during sputtering, in particular during magnetron sputtering: the different expansion coefficients of the various mechanical and chemical properties of polymers and oxides often lead to inadequate layer adhesion and crack formation.

In the case of vapor coating processes, an attempt is made to compensate for the above-mentioned defects by applying very non-compact and relatively soft coatings. However, the quality of the applied layers is very poor. Alternatively, an attempt is made to apply pure polymer coatings on plastic material substrates, the polymer coatings reacting insensitively to mechanical stresses. However, the same desired optical, electrical and mechanical properties, as in the case of metal- or metal oxide coatings, often cannot be achieved with the polymer coatings.

Polymer layers are frequently produced from the liquid phase by means of spin coating or dip coating. Application of the polymer layers in sputtering processes for example is usually not an option since, because of the high particle energies of the ions, the organic bonds are often destroyed. In the state of the art, a low-energy coating technology by the name of “matrix assisted pulse laser evaporation” for depositing polymers from the gas phase is known in order to address this problem. This is described for example in U.S. Pat. No. 6,025,036. Monomers are thereby dissolved in a solvent which is then deep-frozen with liquid nitrogen. A pulsed excimer laser heats this monomer source so that solvent and individual monomers change into the gas phase. From the gas phase, the monomers can then be deposited on the substrate surfaces as polymer layer.

The use of a laser for removing the monomers has some disadvantages however. Thus, the production and control of the laser beam is very expensive and the scaling-up for the production of large quantities of coated articles is difficult because of the laser's inadequate ability to be scaled up.

### SUMMARY

In some embodiments, the invention pertains to a method of forming different layers on a substrate that does not suffer from the above-mentioned problems and that allows novel layer systems.

In an embodiment, a first vacuum coating source including at least a first coating material dissolved in a solvent is placed in position. The first coating material bonds better to a substrate than the solvent, at a prevailing low pressure, and the solvent is desorbed out of the first vacuum coating source with irradiation by an irradiation source, as a result of which the first coating material is released from a surface of the first vacuum coating source subjected to the irradiation. Furthermore, a second vacuum coating source which has at least a second coating material is placed in position. The second coating material is released by means of a chemical vapor deposition process and the released first and second layer materials are deposited in this way on the substrate.

The first vacuum coating surface and the second vacuum coating source are positioned such that the released first and second layer materials can be deposited on the substrate from the vacuum coating sources. In the state of the art, control of these method parameters is well known.

In some embodiments, it becomes possible to produce layer systems that have properties not yet available in the state of the art. By means of the first coating material dissolved in a solvent, in particular monomers and polymers can be deposited on the substrate. The first vacuum coating source is thereby a monomer source which is for example deep-frozen by means of liquid nitrogen and is heated by the irradiation source. In contrast to the state of the art, this does not take place with an excimer laser but merely with an adjusted irradiation source. The use of an ion beam source as irradiation source in the method according to embodiments of the invention thereby displays the effect that, with low ion energies and large ion flows or high current densities, the first layer material can be dissolved out of the solvent without destroying the first layer material.

In some embodiments, the second coating material is situated on a second vacuum coating source and can hence be deposited on the substrate before, after or simultaneously with the first coating material. In some embodiments, it is possible when using a second coating material that differs greatly in its properties from those of the first coating material to achieve layer systems that have not previously been achievable.

In some embodiments, the use of an ion beam source contributes in particular to the method for applying the first coating material also being achievable on a large industrial scale. To date, this has been possible only with great difficulty when using the laser. The surprising effect of the ion beam source or even merely the irradiation by means of a direct radiation heating hereby assists in applying the first layer material dissolved in the solvent on the substrate.

In one embodiment of the method according to the invention, the chemical vapor deposition process is a physical chemical vapor deposition process. In some embodiments, the physical chemical vapor deposition is magnetron sputtering or reactive magnetron sputtering. Physical chemical vapor deposition processes are already scalable on a large industrial scale. This applies particularly to magnetron sputtering in which high reaction rates can already be achieved. The thickness of the layer to be applied can also be controlled readily.

In some embodiments, and in order to prevent overheating of the first vacuum coating source, the radiation source can be used in a pulsed operation. High energy inputs which, on the one hand, effect removal of the first layer material from the first vacuum coating layer but, on the other hand, reduce the temporally integrated energy input hereby occur transiently.

In some embodiments, the method is useful if the substrate has a plastic material surface and/or includes a plastic material. It is also possible with this method to improve the adhesive strength of inorganic coatings produced by sputtering or vapor coating on plastic material substrates, such as PMMA, PC or PET.

For optimal adhesion of the layers applied on the substrate, it is advantageous if the plastic material surface is activated via a plasma treatment before deposition of the first and/or second coating material. This has the advantage that the surface can be contacted better by the first and/or second coating material, which improves the adhesion between the substrate and the first and/or second layer.

In a further embodiment of the method according to the invention, firstly a layer of the first coating material is deposited on the substrate and subsequently a layer of the second coating material or a mixed layer, i.e. composite layer made of the first and the second layer material, is deposited on the substrate. The first layer made of the first coating material hereby forms an adhesive layer between the substrate and the following layers. The term “adhesive layer” should thereby not only be understood such that the adhesion between the substrate and the first layer is improved but also such that the adhesion between the first layer and the second layer is substantially improved. In some embodiments, when using mixed layers, gradient layers which are composed differently can be produced, which layers can be examined under process parameters as to their mechanical properties, such as for example deformation, adhesive strength, hardness and crack formation in various compositions, and subsequently can be produced.

In a further embodiment of the method, the first coating material and the second coating material are deposited on the substrate at the same time as one layer. As a result, the production of the above-mentioned mixed layers is greatly simplified. The thus configured mixed layer need not thereby necessarily be applied as first, second or third layer but can be applied at any point in time.

In an embodiment, the first layer material is a monomer or a polymer. This is advantageous in particular in conjunction with a plastic material substrate or a substrate with a plastic material surface since the first coating material hereby forms the above-mentioned adhesive layer. There are possible as polymers, for example PET, PMMA or PEG.

Furthermore, in some embodiments it is advantageous if the second coating material is a metal such as aluminium, silicon, niobium or titanium, or a metal mixture, such as e.g. In:Sn, or a metal ceramic, such as e.g. SiO₂, Si₂N₄, Al₂O₃, NbOx, TiOx, TaOx, In₂O₃:Sn, MgF₂ or MgO. By depositing metals in a pure, alloyed or ceramic form, it is possible to equip the substrates or the articles having the substrates with a very hard and crack-resistant layer. In some embodiments, the second coating material is thereby applied on a layer of the first coating material that includes a polymer or monomer or another organic material in order hence to improve the adhesion between a substrate, such as a plastic material substrate, and the metal layer. In this way, articles that include a substrate and have a metal- or metal oxide layer can be produced, which could not previously be applied on the plastic material substrate or not with the desired quality because of the lack of adhesive strength.

In a further embodiment of the method, the first and the second vacuum coating source are at a spacing from each other and in some embodiments may be separated from each other by a coating protection. In this way, in particular the more sensitive first layer material can be applied without being disturbed by the application method of the second layer material, which increases the yield and hence the layer quality in particular of the first coating material. There can serve as coating protection, for example a simple shielding metal sheet between the first and the second vacuum coating source.

In a further embodiment, the uncoated substrate is guided, on a moveable substrate holder, past the first and the second vacuum coating source. When being guided past the first and the second vacuum coating source, the uncoated substrate is coated, the coating being able to include both of a plurality of pure layers made of either the first or the second material or also being able to include individual layers made of mixed layers which have both the first and the second layer material.

It will be appreciated that in some embodiments, the method steps described above may be combined.

In some embodiments, a system for coating a substrate with a layer system may have a coating chamber, a substrate holder, a first vacuum coating source such as a first coating material dissolved in a solvent and an irradiation source, a second vacuum coating source including a second coating material, and a device for chemical vapor deposition. Coating chambers are extensively known in the state of the art and are not intended to be discussed further here.

By means of an embodiment of the method according to the invention, an article can be produced which has a substrate provided with a layer system, the substrate having a plastic material and the layer system at least a first and a second layer. The first layer can be formed by a pure polymer layer, such as e.g. PMMA, PE, PP, PC, PET, PVC, PTFE, a copolymer layer or from an organic, non-polymer layer, such as e.g. from organic color pigments or organic molecules with special groups. The second layer can include a composite layer made of polymer or organic material and metal, such as Si, Al, Ti, Nb, Cu, Cr or C. Also a composite layer made of polymer or organic material and metal ceramics, such as oxides, but also fluorides and nitrides, such as e.g. SiO₂, Si₃N₄, Al₂O₃, NbOx, TiOx, TaOx, In₂O₃:Sn, MgF₂ or MgO, is advantageous.

Furthermore, the second layer or a further layer disposed on the second layer can also be a simple metal- or metal ceramic layer.

In some embodiments, it is possible to produce an adhesion-promoting effect between the substrate and metal- or metal ceramic layers as a result of a layer gradient between the organic material and the metal oxide that was not producible with previous methods. Furthermore, the elasticity of the normally hard and brittle metal- and metal ceramic layers is increased by the supply of organic layer components and polymers. Resulting herefrom is greater flexibility and ductility of the layers, less crack formation and higher mechanical resistance.

Numerous applications can be implemented or produced via embodiments of the methods described herein. Examples include producing adhesion-promoting layers for physical chemical vapor deposition processes, producing flexible, crack-resistant, optical layer systems on plastic material plates or films such as, for example, antireflection coatings, optical filters or contrast-increasing screens on plastic material films and configuring flexible, crack-resistant optical layer systems as multiple layer stacks of high and low-refractive metal oxide-polymer composite layers. Further examples include adhesive and flexible scratch resistant layers on plastic substrates such as PMMA via a physical chemical vapor deposition process and sub layers for photocatalytic layers such as anatase TiO₂ on plastic substrates such as PMMA via physical chemical vapor deposition. Additional examples include diffusion barriers for oxygen and/or water on plastic plates and films, antistatic coatings on plastic plates and films, electrically conductive oxides on plastic plates and films, and adhesive deposition of organic layer components having special functional groups for medical technology and chemical analysis.

In some embodiments, polymers and biopolymers may be incorporated. Hence completely new properties can be achieved. These biopolymers can be applied for example as monomer or else also directly as biopolymer from the source onto the layer. Non-limiting examples include proteins, peptides, polysaccharides such as starch, cellulose and glyocen, and polyglucosamines such as chitin and chitosan.

In some embodiments, the use of a second vacuum coating source and the device for chemical vapor deposition associated therewith can be dispensed with so that articles with one or more pure polymer layers can be produced. The advantageousness of the ion beam source then resides, as previously described, in the greatly improved ability to be scaled up in comparison with a laser. By using the ion beam source, application of the first layer material onto a plastic material substrate can be improved. Possible layer and/or substrate materials can be deduced from the preceding sections. By means of this method, articles which have a substrate made of a plastic material with a pure polymer or copolymer layer applied thereon can be produced.

### BRIEF DESCRIPTION OF THE FIGURES

Further aspects of the invention are intended to be discussed more precisely within the scope of the embodiments. There are shown:

FIG. 1a,b are schematic illustrations embodiments of a system in accordance with embodiments of the invention.

FIG. 2 is a schematic illustration of an article according to an embodiment of the invention.

### DETAILED DESCRIPTION

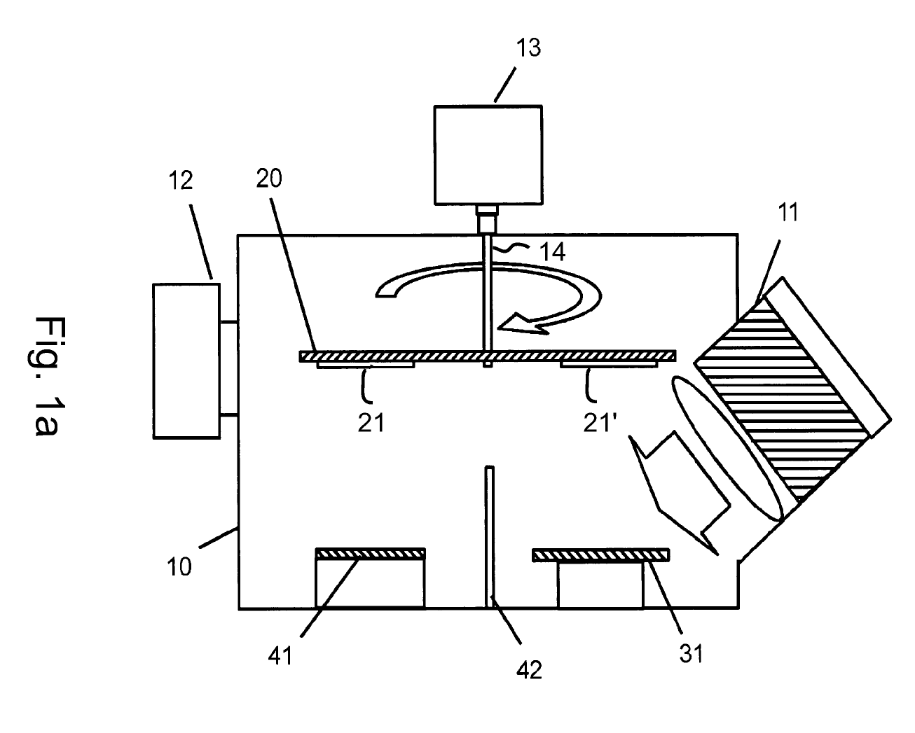

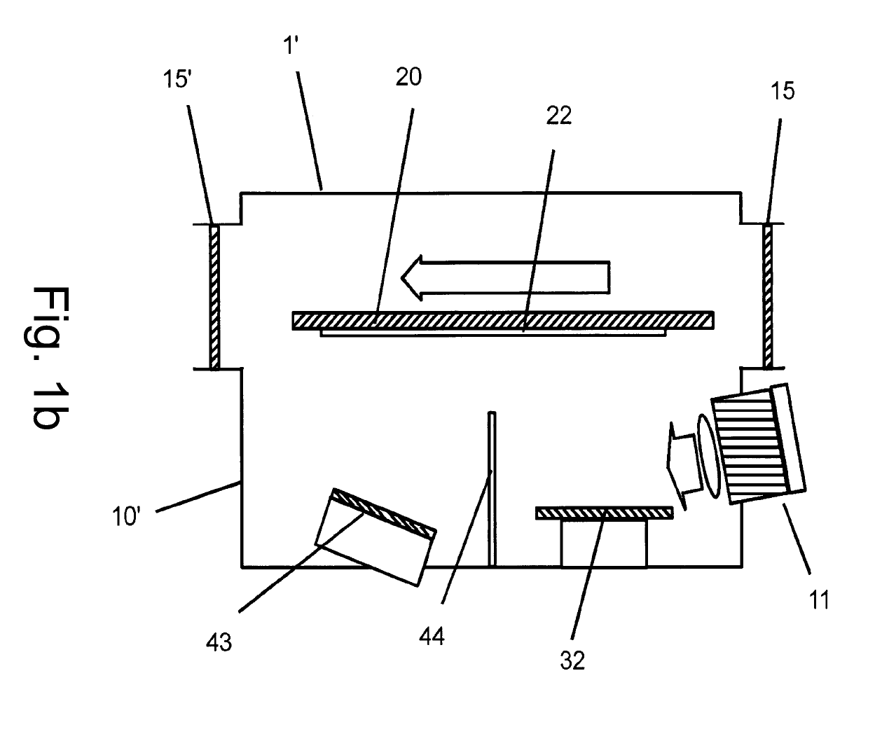

FIG. 1a illustrates an embodiment of a system 1 for implementing the method is represented. The system 1 has a coating chamber 10 in which an ion beam source 11, a turbopump 12 and a rotary motor 13 with a rotary axle 14 secured thereon are disposed. A substrate holder 20 for retaining substrates 21, 21′ is disposed on the rotary axle 14. The substrate holder 20 is rotated about the rotary axle 14 via the rotary motor 13.

In some embodiments, the ion beam source 11 is disposed such that the latter irradiates a first vacuum coating source 31. The irradiation is effected with low-energy ions with high current densities in order not to destroy the first coating material situated in the first vacuum coating source 31.

In some embodiments, the first vacuum coating source 31 includes a deep-frozen first coating material dissolved in a solvent. The first coating material, in an embodiment, is a monomer made of methylmethacrylate. During irradiation of the first vacuum coating source 31 with the low-energy ions, the solvent is desorbed from the first coating material whereupon the first coating material is released from the surface of the first vacuum coating source 31 orientated towards the substrate 21 and, because of the prevailing low pressure in the coating chamber 10, is deposited on the substrates 21 or 21′. During the desorption of the solvent out of the first vacuum coating source 31 and the thereupon released monomers, the monomers bond either on the path between the first vacuum coating source 31 and the substrates 21 or 21′ to form polymers or the bonding to form polymers only takes place on the substrate 21 or 21′ itself.

In some embodiments, the substrates 21 or 21′ are plastic material plates or films made of PMMA. The first layer material then forms a polymer layer on the surface of the substrate 21 as a result of the irradiation so that a first pure polymer layer is formed on the bare PMMA. The method functions however also if the uncoated surface of the substrates includes PMMA.

As mentioned already, a low pressure which is produced via the turbopump 12 prevails in the coating chamber 10. The operating pressure thereby is in the range between 10⁻¹ to 10⁻⁷ mbar in the coating chamber. In some embodiments, an operating pressure of 10⁻² to 10⁻⁴ mbar is maintained in the coating chamber.

In addition to the first vacuum coating source 31, a second vacuum coating source 41 is situated in the coating chamber 10. The first vacuum coating source 31 and the second vacuum coating source 41 are thereby separated from each other spatially by a coating protection 42, the significance of the separation being dealt with in more detail at a subsequent point. The second vacuum coating source 41 has a second coating material which, in some embodiments, is titanium. Between the second vacuum coating source 41 and the substrate holder 20, an electrical field is applied, on the one hand, and, on the other hand, a magnetron with which a magnetic field can be applied to the second vacuum coating source 41 is situated below the second vacuum coating source 41. In the surroundings between the second vacuum coating source 41 and the substrate holder 20, a plasma is situated, as is known in the case of magnetron sputtering. The coating protection 42 prevents plasma and hereby in particular the highly reactive oxygen ions also extending into the partial region of the coating chamber 10 which is situated between the first vacuum coating source 31 and the substrate holder 20. Hence, the reactive oxygen ions are intended to be prevented from attacking the monomers which have been detached from the first vacuum coating source 31 by oxidation before said monomers can form a polymer layer on the substrate 21 or 21′.

The titanium from the second vacuum coating source 41 is deposited on the substrate 21′ or 21 by means of magnetron sputtering. Oxygen is thereby added to the plasma which is formed as normal by argon ions so that the titanium dissolved out of the second vacuum coating source 41 combines with the oxygen to form a titanium oxide. The titanium oxide is subsequently deposited on the substrate 21′ or 21 as a thin layer.

In some embodiments, the system 1 represented in FIG. 1a can be operated in a plurality of operating modes. In a first operating mode, the substrates 21 or 21′ can firstly be coated with a polymer layer by means of the ion beam source 11. This becomes possible since the rotary motor 13 rotates the substrate holder 20 about the rotary axle 14 and thus all the substrates situated on the substrate holder can be covered with the polymer layer. After a sufficient thickness of the polymer layer has been produced on the PMMA, the polymer coating process is stopped and the titanium of the second vacuum coating source 41 is dissolved out of the second vacuum coating source 41 by means of magnetron sputtering. In this way, a second layer is deposited on the first layer of the substrate, which second layer can consist of a titanium oxide, in general a metal oxide, semimetal oxide, metal, semimetal or a metal ceramic. In this way, mechanically flexible high- and low-refractive optical layers inter alia can be deposited. By the production of stacks of layers, thus mechanically flexible optical layer systems and a broad band antireflection layer system or optical filters can be achieved.

In comparison with previously known substrates made of PMMA, these optical layer systems are readily adhesive since they are not deposited directly on the substrate made of PMMA itself but on a PMMA metal oxide transition layer with stronger interlocking and chemical bonding between polymer and metal oxide. Hence the layers applied on the substrate have good quality, the metal oxide layer being prevented in particular from adhering poorly or forming cracks.

In some embodiments, firstly a first layer made of a polymer can be deposited on the substrate 21 or 21′ and subsequently a mixed layer can be applied, during simultaneous operation of the ion beam source 11 and of the magnetron of the second vacuum coating source 41, during rotation of the substrate holder 20 along the rotary axle 14, which mixed layer includes a polymer and a metal oxide. The concentration of the individual components of the mixed layers, i.e. the percentages by weight of the first and of the second layer material, can be adjusted for example via the deposition rates of the first or of the second layer material or also by adjusting the speed of rotation of the substrate holder 20. In this way, the layer properties can be changed, which contributes in particular to new possibilities for the hardness, elasticity and the refractive and absorption index and the layer adhesion. Furthermore, a further metal- or metal oxide layer could be applied on such a mixed layer by means of magnetron sputtering or another physical chemical vapor deposition process. Also other physical deposition processes, such as e.g. thermal evaporation, electron beam evaporation or ion beam sputtering, are possible for application of the second layer material, in addition to magnetic sputtering.

In FIG. 1b, a further system 1′ is represented, which is readily suitable in particular for the production of coated substrates on a technical industrial scale. The system 1′ has a coating chamber 10′ in which a substrate holder 20′ can be introduced via an entrance lock 15 and can be moved out via an exit lock 15′. The guide device of the substrate holder 20′, which is not represented in the drawing, guides, in the present example, the substrate from right to left. This means in particular that the substrate 22 applied on the substrate holder 20′ is not yet coated on the right entrance side of the coating chamber 10′ but is coated with various layers at the exit from the coating chamber 10′ through the lock 15′. To the right of the lock 15 or to the left of the lock 15′, i.e. outside the represented coating chamber 10′, adjacent inline segments are situated for pre-treatment and deposition of further layers. Thus, the substrate can be activated in the inline segment to the right of the lock 15 by means of plasma treatment. The coating chamber 10′ is under a low pressure which is comparable to the low pressure of the system 1 of FIG. 1a, i.e. the low pressure changes by the same order of magnitude. In turn, an ion beam source 11 which irradiates a first vacuum coating source 32 is represented. The first vacuum coating source 32, similarly to the first vacuum coating source 31 of FIG. 1a, is a first coating material which is present dissolved in a solvent.

In some embodiments, the ion beam source 11 extends in the focal plane so that the first vacuum coating source 32 is irradiated over the entire width of the substrate 22, extending in the focal plane, with low-energy ions so that a first polymer layer can extend over the entire width of the substrate 22 protruding in the focal plane. The substrate 22 includes a plastic material substrate made of PET. In some embodiments, the first layer material of the first vacuum coating source 32 is polymethylmethacrylate (PMMA), but can also be a polyethyleneglycol (PEG). Firstly a PMMA layer is therefore applied on the substrate 22. When the substrate 22 is moved via the moveable substrate holder 20′, the substrate 22 now coated with a first PMMA layer is transported further to the left beyond a coating protection 44 that separates the coating process of the first layer from the coating process of a second layer. The second coating process is effected via a second vacuum coating source 43. As illustrated, the second vacuum coating source 43 is disposed at a slight angle relative to the wall of the coating chamber 10′ so that some atoms of the second layer material of the second vacuum coating source 43, which atoms are atomized by means of magnetron sputtering, can form, together with some particles of the first layer material of the first vacuum coating source 32, a mixed layer on the substrate 22.

In some embodiments, the second layer material of the second vacuum coating source 43 is silicon, the plasma situated between the substrate 22 and the second vacuum coating source 43 being enriched with oxygen to form a reactive plasma so that the layer deposited on the substrate is a silicon oxide. Of course, also a pure metal, such as for example aluminium, chromium or titanium or the ceramic forms thereof, could be deposited on the substrate. After a pure layer of the second layer material has been deposited on the substrate 22 provided with the first layer and the mixed layer, the substrate disposed on the substrate holder 20′ leaves the coating chamber 10′ through the lock 15′ for further processing.

As can be detected easily in the example of FIG. 1b, the method according to the invention or the embodiments thereof is simple and able to be scaled up for deposition of flexible optical layer systems with good layer adhesion and a low tendency towards crack formation, in particular in the case of critical requirements, such as external applications or moisture or mechanical stress. Furthermore, layers with improved properties can be produced, the improved properties being able to be adjusted in particular via the mixing between the first and the second layer material in a mixed layer. Furthermore, it is well illustrated in FIG. 1b how the new method or the system for implementing the method can be integrated into existing processes, the integration being relatively economical and, in the long term, new applications, such as e.g. active components in optoelectronics, become possible. This is, on the one hand, due to the fact that the homogeneous deposition of first and second layers or mixed layers becomes possible also on large areas, such as e.g. films or plates. With the systems for implementing the method and the different embodiments of the method, new and better optical layer systems can be produced, such as e.g. antireflection layers, filters or selective mirrors which can be used in automobile construction, in the field of consumer optics, in opthalmics, in medical technology, in sensor technology or in display technology.

The systems 1 or 1′ shown in FIGS. 1a and 1b can, instead of an ion beam source 11, also have a radiation heating for irradiating the first vacuum coating source 31 or 32. Also with a metered irradiation of the first vacuum coating source, it is possible to desorb the solvent and to detach the first layer material so that the latter can be deposited on a substrate in the form of a layer.

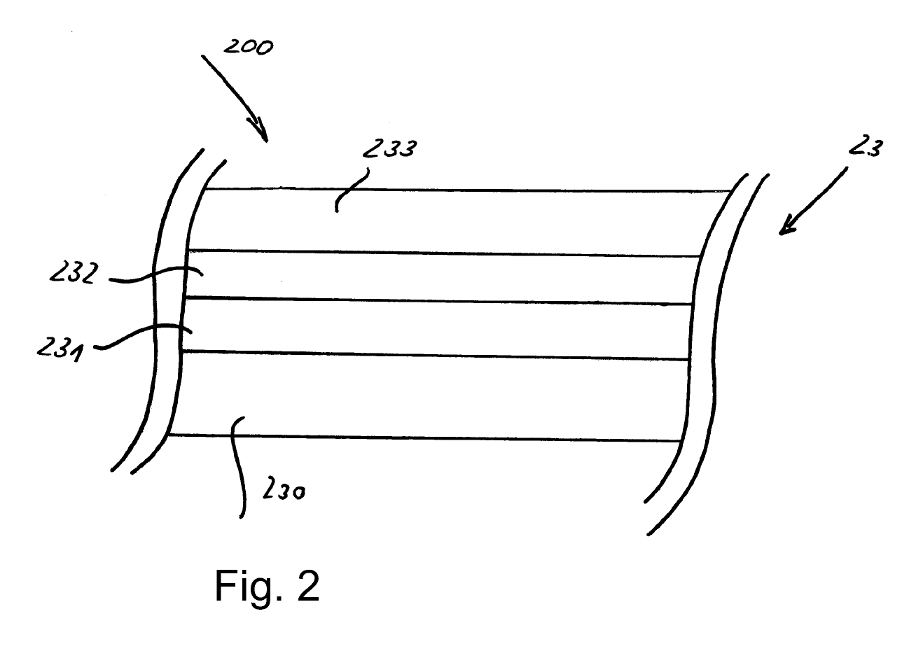

FIG. 2 illustrates a coated substrate 23 that can be produced by means of various embodiments of the method according to the invention. The coated substrate 23 has a plastic material 230 which represents an uncoated substrate. The plastic material 230 itself can for example be a PMMA, PC or PET. A first layer 231 which includes a polymer, such as for example polymethylmethacrylate or polyethyleneglycol, is applied on said plastic material. A mixed layer 232 which consists both of a first and a second layer material is applied on the first layer 231, the first layer material being a polymer and the second layer material a metal or metal oxide. A second layer 233 which includes a metal or metal oxide is applied on the mixed layer 232. As alternative materials for substrate and first and second layer material, reference may be made to the preceding sections. The thickness of the various layers can vary between a few nm to a few μm. For optical layers systems, the individual layer thicknesses are in the range between 1 nm to several 100 nm.

The coated substrate 23 illustrated here can then be processed further to form articles as have been already described previously

1-18. (canceled)

19. A method for producing a layer system on a substrate, the method comprising steps of:
positioning a first vacuum coating source including at least a first coating material dissolved in a solvent, the first coating material bonding better to the substrate than the solvent, at a low pressure, and the solvent being desorbed out of the first vacuum coating source when irradiated by an irradiation source;
positioning a second vacuum coating source which has at least a second coating material; and
irradiating the first vacuum coating source via an irradiation source, the solvent being desorbed by the radiation impinging on the first vacuum coating source and the first coating material being released from a surface of the first vacuum coating source, and the second coating material being released via a chemical vapor deposition process and the released first and second coating material being deposited on the substrate.

20. The method according to claim 19, wherein the chemical vapor deposition process is a physical chemical vapor deposition process.

21. The method according to claim 19, wherein the irradiation source is a heat beam, an ion source or an electron beam source.

22. The method according to claim 19, wherein the irradiation source is pulsed or operated at radio frequency.

23. The method according to claim 19, wherein the substrate includes a plastic material surface.

24. The method according to claim 23, wherein the plastic material surface is activated via plasma treatment before deposition of the first and/or second layer material.

25. The method according to claim 23, wherein firstly a layer of the first coating material is deposited on the substrate and subsequently a layer of the second coating material or a mixed layer made of the first and the second coating material is deposited on the substrate.

26. The method according to claim 19, wherein the first coating material and the second coating material are deposited on the substrate at the same time as one layer.

27. The method according to claim 19, wherein the first coating material is a monomer or a polymer.

28. The method according to claim 27, wherein the polymer is a PE (polyethylene), PP (polypropylene), PVC (polyvinylchloride), PS (polystyrene), PTFE (polytetrafluoroethylene), PMMA (polymethylmethacrylate), PA (polyamide), polyester, PC (polycarbonate) or PET (polyethyleneterephthalate), PEG (polyethyleneglycol) or polyacrylic acid.

29. The method according to claim 27, wherein the polymer is a biopolymer.

30. The method according to claim 19, wherein the second layer material comprises a metal, a metal mixture, or a ceramic.

31. The method according to claim 19, wherein the first vacuum coating source and the second vacuum coating source are spaced apart.

32. The method according to claim 31, wherein the first vacuum coating source and the second vacuum coating source are separated from each other by a coating protection element.

33. The method according to claim 19, wherein the substrate is guided, on a moveable substrate holder, past the first vacuum coating source and the second vacuum coating source.

34. A system for coating a substrate with a layer system, the system comprising:
a coating chamber;
a substrate holder;
a first vacuum coating source made of a first layer material dissolved in a solvent;
an irradiation source;
a second vacuum coating source with a second layer material; and
a device for chemical vapor deposition so that the second layer material can be deposited on the substrate.

35. A method for producing a layer system on a substrate, the method comprising steps of:
positioning a first vacuum coating source that includes at least a first layer material dissolved in a deep-cooled solvent, the first layer material bonding better to the substrate than the solvent, at a low pressure, and the solvent being desorbed out of the first vacuum coating source with irradiation by an ion source, as a result of which the first layer material is released from a surface of the first vacuum coating source subjected to the irradiation; and
irradiating the first vacuum coating source via an ion source, the ions impinging on the first vacuum coating source desorbing the solvent out of the first vacuum coating source and the released first layer material being deposited on the substrate.
